(19) United States
(12) Patent Application Publication
(10) Pub. No.: US 2026/0342295 A1
(43) Pub. Date: Oct. 29, 2026

(54) TRANSCEIVER WITH PHASE COMPENSATION CIRCUIT

(71) Applicant: Realtek Semiconductor Corp., HsinChu (TW)

(72) Inventors: Ping-Hsuan Tsai, HsinChu (TW); Chia-Jun Chang, HsinChu (TW)

(73) Assignee: Realtek Semiconductor Corp., HsinChu (TW)

(21) Appl. No.: 19/634,043

(22) Filed: Mar. 30, 2026

(30) Foreign Application Priority Data
Apr. 25, 2025 (TW) 114115661

(51) Int. Cl. H03F 3/24; H03D 7/00; H03H 7/18; H04B 1/44

(52) U.S. Cl. CPC H03F 3/245; H03H 7/18; H04B 1/44; H03D 7/00; H03F 2200/294; H03F 2200/451

(57) ABSTRACT

The present invention provides a transceiver including a transmitting circuit, wherein the transmitting circuit includes a baseband amplifier, a mixer, a power amplifier and a phase compensation circuit. The baseband amplifier is configured to amplify a baseband signal to generate a baseband transmission signal. The mixer is configured to mix the baseband transmission signal using an oscillation signal to generate a RF transmission signal. The power amplifier is configured to amplify the RF transmission signal to generate an amplified RF transmission signal for transmission to an antenna. The phase compensation circuit is coupled to an output terminal or an input terminal of the baseband amplifier, and configured to compensate for a phase of the baseband transmission signal; or the phase compensation circuit is coupled to an output terminal or an input terminal of the power amplifier, and configured to compensate for a phase of the amplified RF transmission signal.

### BACKGROUND OF THE INVENTION

### 1. Field of the Invention

The present invention relates to a transceiver, and more particularly to a transceiver with phase compensation functionality.

### 2. Description of the Prior Art

In a phase array antenna system, setting multiple phase shifters corresponding to multiple antennas can generate constructive or destructive interference in the radiation pattern to achieve beamforming. Therefore, the phase variations generated by the transceiver coupled to the antenna when processing transmitted signals and received signals will affect the effectiveness of beamforming.

Taking the receiver within the transceiver as an example, to enable receiving signals of varying magnitudes from the antenna, the receiver includes a gain-adjustable amplifier for different gain configurations. However, because the received signals undergo different phase variations when passing through amplifiers with varying gains, the receiver may fail to achieve the intended beamforming effect under certain gain configurations, thereby impacting subsequent signal processing.

### SUMMARY OF THE INVENTION

Therefore, one of the objectives of the present invention is to propose a transceiver that includes a phase compensation circuit to compensate for phase variations caused by different gain configurations thereby addressing the problems described in the prior art.

According to one embodiment of the present invention, a transceiver comprising a transmitting circuit is disclosed. The transmitting circuit comprises a first baseband amplifier, a first mixer, a power amplifier and a first phase compensation circuit. The first baseband amplifier is configured to amplify a baseband signal to generate a baseband transmission signal. The first mixer is configured to mix the baseband transmission signal using a first oscillation signal to generate a radio frequency (RF) transmission signal. The power amplifier is configured to amplify the RF transmission signal to generate an amplified RF transmission signal for transmission to an antenna. The first phase compensation circuit is coupled to an output terminal or an input terminal of the first baseband amplifier, and configured to compensate for a phase of the baseband transmission signal; or the first phase compensation circuit is coupled to an output terminal or an input terminal of the power amplifier, and configured to compensate for a phase of the amplified RF transmission signal.

According to one embodiment of the present invention, a transceiver comprising a receiving circuit is disclosed. The receiving circuit comprises a low-noise amplifier, a mixer, a baseband amplifier and a first phase compensation circuit. The low-noise amplifier is configured to amplify a radio frequency (RF) receiving signal to generate an amplified RF receiving signal. The mixer is configured to mix the amplified RF receiving signal using an oscillation signal to generate a baseband receiving signal. The baseband amplifier is configured to amplify the baseband receiving signal to generate an amplified baseband receiving signal. The first phase compensation circuit is coupled to an output terminal or an input terminal of the low-noise amplifier, and configured to compensate for a phase of the amplified RF receiving signal; or the first phase compensation circuit is coupled to an output terminal or an input terminal of the baseband amplifier, and configured to compensate for a phase of the amplified baseband receiving signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a transceiver according to an embodiment of the present invention.

FIG. 2 is a schematic diagram of a phase compensation circuit according to an embodiment of the present invention.

FIG. 3 is a schematic diagram of a phase compensation circuit according to an embodiment of the present invention.

FIG. 4 is a schematic diagram of a phase compensation circuit according to an embodiment of the present invention.

### DETAILED DESCRIPTION

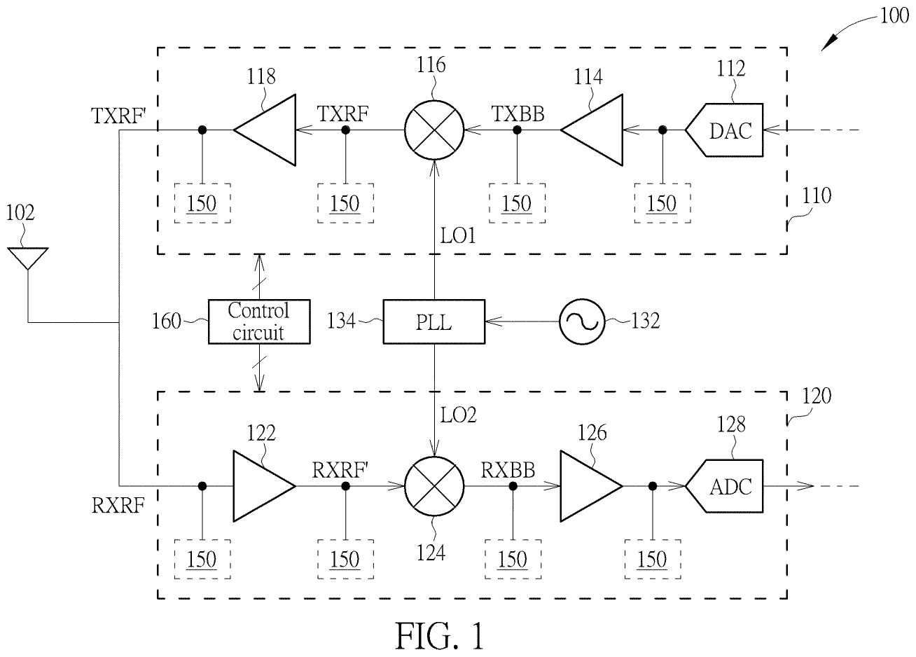

FIG. 1 is a schematic diagram of a transceiver 100 according to an embodiment of the present invention. As shown in FIG. 1, the transceiver 100 includes a transmitting circuit 110, a receiving circuit 120, a voltage-controlled (VCO) oscillator 132, a phase-locked loop (PLL) 134, and a control circuit 160. The transmitting circuit 110 includes a digital-to-analog converter (DAC) 112, a baseband amplifier 114, a mixer 116, and a power amplifier 118. The receiving circuit 120 includes a low-noise amplifier (LNA) 122, a mixer 124, a baseband amplifier 126, and an analog-to-digital converter (ADC) 128. In this embodiment, the transceiver 100 can be integrated into any electronic device having wireless communication capabilities, such as a mobile phone, a tablet computer, a laptop computer, an access point, and so forth. In one embodiment, the transceiver 100 can be applied in any electronic device equipped with a phase array antenna system.

In the main operation of the transmitting circuit 110 of the transceiver 100, the DAC 112 performs a digital-to-analog conversion operation on a digital signal to generate a baseband signal. The baseband amplifier 114 then amplifies this baseband signal to generate a baseband transmission signal TXBB. The mixer 116 uses an oscillation signal LO1 to perform a mixing operation (up-conversion operation) on the baseband transmission signal TXBB to generate a radio frequency (RF) transmission signal TXRF. The oscillation signal LO1 is generated by the PLL 134 processing a clock signal generated by the VCO 132. Then, the power amplifier 118 amplifies the RF transmission signal TXRF to generate an amplified RF transmission signal TXRF′. This amplified RF transmission signal TXRF′ is then transmitted to other electronic devices via an antenna 102. In the main operation of the receiving circuit 120 of the transceiver 100, the LNA 122 receives an RF receiving signal RXRF from the antenna 102 and amplifies it to generate an amplified RF receiving signal RXRF′. Next, the mixer 124 uses an oscillation signal LO2 to perform a mixing operation (down-conversion operation) on the amplified RF receiving signal RXRF′ to generate a baseband receiving signal RXBB. The oscillation signal LO2 is generated by the PLL 134 processing a clock signal generated by the VCO 132. Subsequently, the baseband receiving signal RXBB is amplified by the baseband amplifier 126 to generate an amplified baseband receiving signal. This amplified baseband receiving signal then undergoes an analog-to-digital conversion operation by the ADC 128 to generate a digital signal for processing by a backend circuit.

As described in the prior art, to enable the receiving circuit 120 to receive signals of varying magnitudes from the antenna 102, the LNA 122 and/or the baseband amplifier 126 within the receiving circuit 120 are equipped with a gain switching function. The control circuit 160 sets different gain values for the LNA 122 and/or the baseband amplifier 126 under different operating modes. Similarly, to enable the transmitting circuit 110 to transmit signals with varying power via the antenna 102, the baseband amplifier 114 and/or the power amplifier 118 within the transmitting circuit 110 are equipped with a gain switching function. The control circuit 160 sets different gain values for the baseband amplifier 114 and/or the power amplifier 118 under different operating modes. However, the switching of gain causes the signals to undergo different phase variations when passing through the aforementioned amplifiers, which may affect the effectiveness of antenna beamforming. For example, assuming that when the power amplifier 118 has a first gain value, the impedance at its output terminal can be represented as Z1=R1+jX1. When the power amplifier 118 has a second gain value, the impedance at its output terminal can be represented as Z2=R2+jX2. Here, the values of the imaginary parts, “X1” and “X2”, reflect the phase of the amplified RF transmission signal TXRF′. Therefore, the difference between “X1” and “X2” is the phase difference caused by the power amplifier 118 switching from the first gain value to the second gain value, and this phase difference affects the effectiveness of antenna beamforming.

Therefore, to address the phase difference caused by the gain switching of the aforementioned power amplifier 118, baseband amplifier 114, LNA 122, and/or baseband amplifier 126 on the signals, this embodiment incorporates a phase compensation circuit 150 at one or more specific nodes, to compensate for the phase difference caused by the aforementioned amplifiers during gain switching, thereby preventing any adverse impact on the antenna beamforming effect.

In one embodiment, the phase compensation circuit 150 can be positioned at either the output terminal or input terminal of any amplifier with gain adjustment capabilities. For example, the phase compensation circuit 150 can be positioned at the output terminal or input terminal of the power amplifier 118, the output terminal or input terminal of the baseband amplifier 114, the output terminal or input terminal of the LNA 122, and/or the output terminal or input terminal of the baseband amplifier 126. In another example, the phase compensation circuit 150 can be positioned solely at the output terminal of the power amplifier 118 and the input terminal of the LNA 122.

When the phase compensation circuit 150 is positioned at the output terminal or input terminal of the baseband amplifier 114, it compensates for the phase of the baseband transmission signal TXBB. For example, the phase compensation circuit 150 compensates for the phase difference caused by the baseband amplifier 114 on the baseband transmission signal TXBB during gain switching. When the phase compensation circuit 150 is positioned at the output terminal or input terminal of the power amplifier 118, it compensates for the phase of the amplified RF transmission signal TXRF′. For example, the phase compensation circuit 150 compensates for the phase difference caused by the power amplifier 118 on the amplified RF transmission signal TXRF′ during gain switching. When the phase compensation circuit 150 is positioned at the output terminal or input terminal of the LNA 122, it compensates for the phase of the amplified RF receiving signal RXRF′. For example, the phase compensation circuit 150 compensates for the phase difference caused by the LNA 122 on the amplified RF receiving signal RXRF′ during gain switching. When the phase compensation circuit 150 is positioned at the output terminal or input terminal of the baseband amplifier 126, it compensates for the phase of the amplified baseband receiving signal. For example, the phase compensation circuit 150 compensates for the phase difference caused by the baseband amplifier 126 on the amplified baseband receiving signal during gain switching.

In one embodiment, the control circuit 160 is coupled to the phase compensation circuit 150, which controls the configuration of the phase compensation circuit 150 based on the gain value of the baseband amplifier 114 or the gain value of the power amplifier 118, to compensate for the phase difference caused by the baseband amplifier 114 on the baseband transmission signal TXBB during gain switching, or to compensate for the phase difference caused by the power amplifier 118 on the amplified RF transmission signal TXRF′ during gain switching. Furthermore, the control circuit 160 controls the configuration of the phase compensation circuit 150 based on the gain value of the LNA 122 or the gain value of the baseband amplifier 126. This compensates for the phase difference caused by the LNA 122 on the amplified RF receiving signal RXRF′ during gain switching, or for the phase difference caused by the baseband amplifier 126 on the amplified baseband receiving signal during gain switching.

In one embodiment, the phase compensation circuit 150 can provide both positive phase adjustment and negative phase adjustment capabilities to compensate for the phase difference caused by the aforementioned amplifiers during different gain switching operations. For instance, assume the power amplifier 118 has eight sets of switchable gain values, G1-G8, with G1 being the default gain value. In this case, the control circuit 160 determines the configuration of the phase compensation circuit 150 based on the current gain value of the power amplifier 118. In one embodiment, if the phase difference caused by the power amplifier 118 on the amplified RF transmission signal TXRF′ when its gain value switches from G1 to G3 is “ΔX”, then the control circuit 160 configures the phase compensation circuit 150 such that the phase difference it introduces to the amplified RF transmission signal TXRF′ is approximately “−ΔX”. This ensures that the gain switching of the power amplifier 118 does not affect the phase of the amplified RF transmission signal TXRF′.

In one embodiment, the control circuit 160 can configure the phase compensation circuit 150 via a look-up table. This look-up table records the configurations for the phase compensation circuit 150 when the power amplifier 118, baseband amplifier 114, LNA 122, and/or baseband amplifier 126 having different gain values.

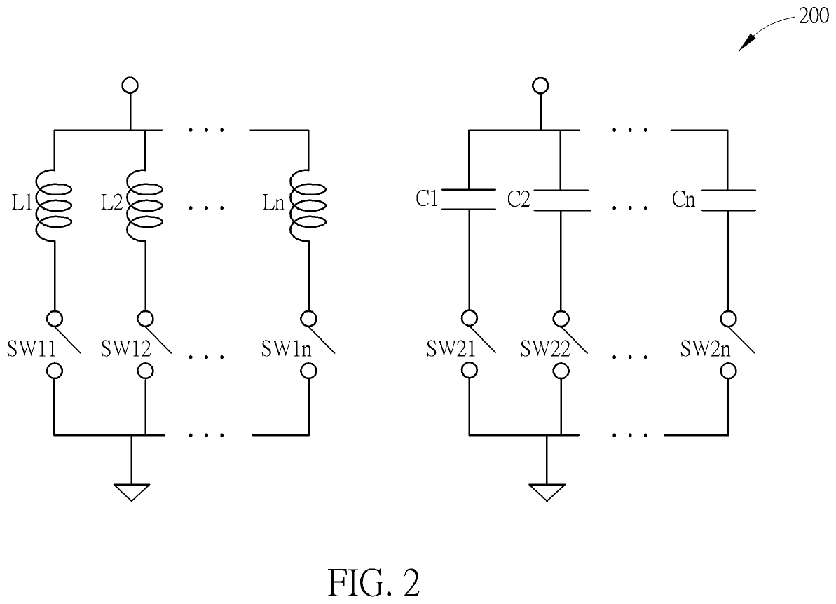

FIG. 2 is a schematic diagram of a phase compensation circuit 200 according to an embodiment of the present invention, wherein the phase compensation circuit 200 can serve as at least a part of the phase compensation circuit 150 shown in FIG. 1. As shown in FIG. 2, the phase compensation circuit 200 includes a switched inductor array and a switched capacitor array. The switched inductor array comprises a plurality of inductors L1-Ln and a plurality of switches SW11-SW1n corresponding to the plurality of inductors L1-Ln. The switched capacitor array comprises a plurality of capacitors C1-Cn and a plurality of switches SW21-SW2n corresponding to the plurality of capacitors C1-Cn. Furthermore, the upper nodes of the switched inductor array and the switched capacitor array are coupled to the input terminal or output terminal of the power amplifier 118, the baseband amplifier 114, the LNA 122, and/or the baseband amplifier 126. The lower nodes of the switched inductor array and the switched capacitor array are coupled to a ground voltage. In the operation of the phase compensation circuit 200, the control circuit 160 controls the capacitance value of the switched capacitor array and/or the inductance value of the switched inductor array based on the gain value of the baseband amplifier 114 or the gain value of the power amplifier 118. Alternatively, the control circuit 160 controls the capacitance value of the switched capacitor array and/or the inductance value of the switched inductor array based on the gain value of the LNA 122 or the gain value of the baseband amplifier 126. Specifically, the control circuit 160 can determine the number of paralleled inductors by controlling the conduction of switches SW11-SW1n, thereby determining the inductance value of the switched inductor array. Similarly, the control circuit 160 can determine the number of paralleled capacitors by controlling the conduction of switches SW21-SW2n, thereby determining the capacitance value of the switched capacitor array. In this embodiment, the impedance of an inductor can be expressed as jωL, which represents a positive phase variation, and the impedance of a capacitor can be expressed as 1/(jωC), which represents a negative phase variation. Therefore, by controlling the inductance value of the switched inductor array and the capacitance value of the switched capacitor array within the phase compensation circuit 200, the phase of the signal in the transceiver 100 (e.g., the phase of the amplified RF transmission signal TXRF′) can be effectively compensated. The aforementioned “ω” refers to the frequency of the signal, “L” refers to the inductance value of the switched inductor array, and “C” refers to the capacitance value of the switched capacitor array.

It should be noted that in the embodiment of FIG. 2, the positions of the plurality of inductors L1-Ln and their corresponding plurality of switches SW11-SW1n within the switched inductor array can be interchanged without affecting the operation of this embodiment. Similarly, the positions of the plurality of capacitors C1-Cn and their corresponding plurality of switches SW21-SW2n within the switched capacitor array can be interchanged without affecting the operation of this embodiment.

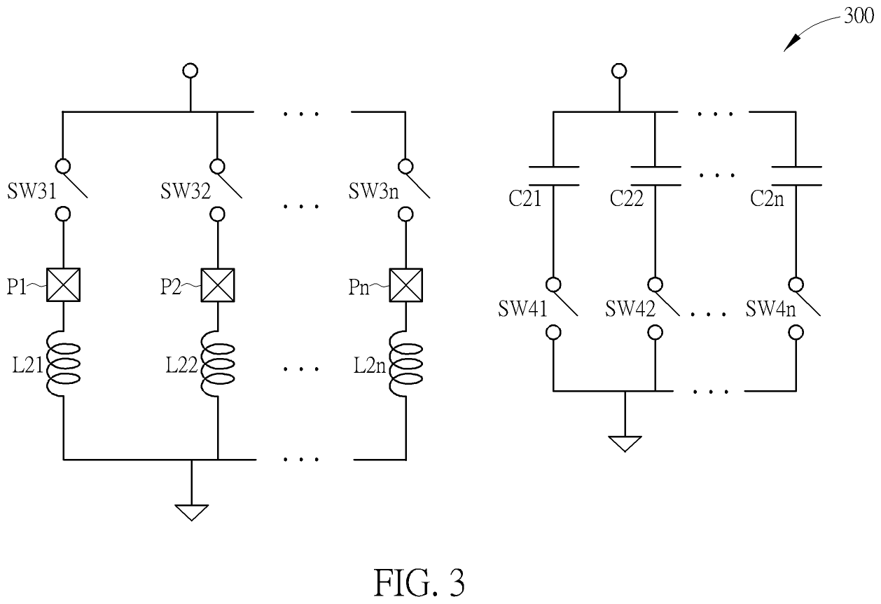

FIG. 3 is a schematic diagram of a phase compensation circuit 300 according to an embodiment of the present invention, where the phase compensation circuit 300 can serve as at least a part of the phase compensation circuit 150 shown in FIG. 1. As shown in FIG. 3, the phase compensation circuit 300 includes a switched inductor array and a switched capacitor array. The switched inductor array comprises a plurality of inductors L21-L2n and a plurality of switches SW31-SW3n corresponding to the plurality of inductors L21-L2n. The switched capacitor array comprises a plurality of capacitors C21-C2n and a plurality of switches SW41-SW4n corresponding to the plurality of capacitors C21-C2n. Furthermore, the upper nodes of the switched inductor array and the switched capacitor array are coupled to the input terminal or output terminal of the power amplifier 118, the baseband amplifier 114, the LNA 122, and/or the baseband amplifier 126. The lower nodes of the switched inductor array and the switched capacitor array are coupled to a ground voltage. In this embodiment, the transceiver 100 has pads P1-Pn. The inductors L21-L2n, which are located external to the transceiver 100, are respectively coupled to the switches SW31-SW3n via the pads P1-Pn. These inductors L21-L2n are implemented using downbonds external to the chip. In the operation of the phase compensation circuit 300, the control circuit 160 can determine the number of paralleled inductors by controlling the conduction of switches SW31-SW3n, thereby determining the inductance value of the switched inductor array. The control circuit 160 can also determine the number of paralleled capacitors by controlling the conduction of switches SW41-SW4n, thereby determining the capacitance value of the switched capacitor array. Therefore, by controlling the inductance value of the switched inductor array and the capacitance value of the switched capacitor array within the phase compensation circuit 300, the phase of the signal in the transceiver 100 (e.g., the phase of the amplified RF transmission signal TXRF′) can be effectively compensated.

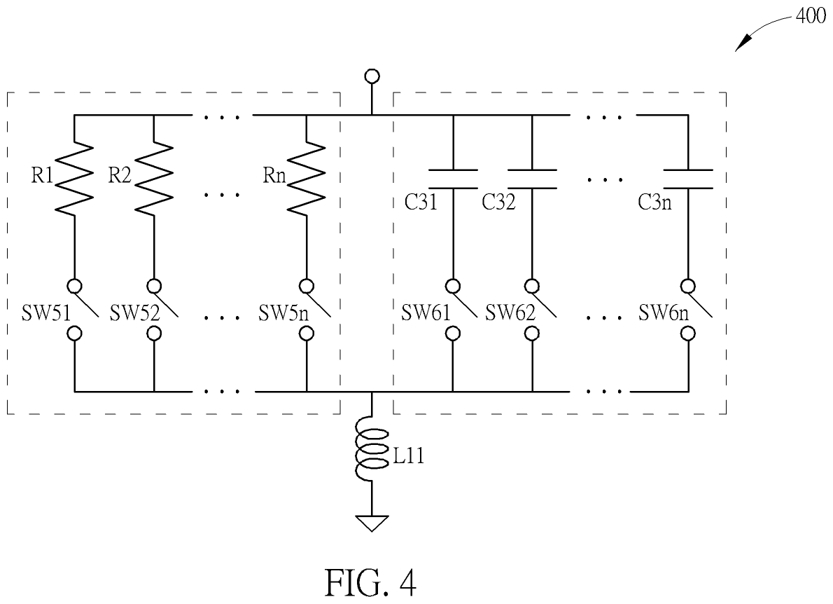

FIG. 4 is a schematic diagram of a phase compensation circuit 400 according to an embodiment of the present invention, wherein the phase compensation circuit 400 can serve as at least a part of the phase compensation circuit 150 shown in FIG. 1. As shown in FIG. 4, the phase compensation circuit 400 includes a switched resistor array, a switched capacitor array, and an inductor L11. The switched resistor array comprises a plurality of resistors R1-Rn and a plurality of switches SW51-SW5n corresponding to the plurality of resistors R1-Rn. The switched capacitor array comprises a plurality of capacitors C31-C3n and a plurality of switches SW61-SW6n corresponding to the plurality of capacitors C31-C3n. Furthermore, the upper nodes of the switched resistor array and the switched capacitor array are coupled to the input terminal or output terminal of the power amplifier 118, the baseband amplifier 114, the LNA 122, and/or the baseband amplifier 126. The lower nodes of the switched resistor array and the switched capacitor array are coupled to a ground voltage via the inductor L11. In the operation of the phase compensation circuit 400, the control circuit 160 controls the capacitance value of the switched capacitor array and/or the resistance value of the switched resistor array based on the gain value of the baseband amplifier 114 or the gain value of the power amplifier 118. Alternatively, the control circuit 160 controls the capacitance value of the switched capacitor array and/or the resistance value of the switched resistor array based on the gain value of the LNA 122 or the gain value of the baseband amplifier 126. Specifically, the control circuit 160 can determine the number of paralleled resistors by controlling the conduction of switches SW51-SW5n, thereby determining the resistance value of the switched resistor array. The control circuit 160 can also determine the number of paralleled capacitors by controlling the conduction of switches SW61-SW6n, thereby determining the capacitance value of the switched capacitor array. In this embodiment, the impedance Z observed from the upper node of the phase compensation circuit 400 can be expressed as:

$$Z = R ‖ ( 1 / j ω C ) + j ω L = \frac{R - j ω {R}^{2} C}{1 + {ω}^{2} {R}^{2} {C}^{2}} + j ω L . \qquad ( 1 )$$

In the above formula (1), “ω” refers to the frequency of the signal, “C” refers to the capacitance value of the switched capacitor array, “R” refers to the resistance value of the switched resistor array, and “L” refers to the inductance value of the inductor L11. In addition, since “1+ω²R²C²” in formula (1) is typically much less than “1”, the impedance in formula (1) can be approximated as R−jωR²C+jωl. As discussed above, by controlling the resistance value of the switched resistor array and the capacitance value of the switched capacitor array within the phase compensation circuit 400, the phase of the signal in the transceiver 100 (e.g., the phase of the amplified RF transmission signal TXRF′) can be effectively compensated.

In one embodiment, the switched resistor array within the phase compensation circuit 400 can be replaced by a fixed resistor. In this scenario, the control circuit 160 can compensate for the phase of the signal within the transceiver 100 by solely controlling the conduction of switches SW61-SW6n to determine the quantity of paralleled capacitors.

In one embodiment, the switched capacitor array within the phase compensation circuit 400 can be replaced by a fixed capacitor, with the fixed capacitor connected in parallel with the switched resistor array. In this case, the control circuit 160 can compensate for the phase of the signal in the transceiver 100 by solely controlling the conduction of switches SW51-SW5n to determine the quantity of paralleled resistors.

It should be noted that in the embodiment of FIG. 4, the positions of the plurality of resistors R1-Rn and their corresponding plurality of switches SW51-SW5n within the switched resistor array can be interchanged without affecting the operation of this embodiment. Similarly, the positions of the plurality of capacitors C31-C3n and their corresponding plurality of switches SW61-SW6n within the switched capacitor array can be interchanged without affecting the operation of this embodiment.

Briefly summarized, the present invention describes a transceiver that effectively mitigates the impact of gain-dependent phase variations on antenna beamforming. This is achieved by incorporating a phase compensation circuit at the input terminal and/or output terminal 1 of one or more amplifiers within the transceiver, wherein this phase compensation circuit effectively compensates for the phase differences introduced to the relevant signals by these amplifiers during gain switching.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transceiver, comprising:
a transmitting circuit, comprising:
a first baseband amplifier, configured to amplify a baseband signal to generate a baseband transmission signal;
a first mixer, configured to mix the baseband transmission signal using a first oscillation signal to generate a radio frequency (RF) transmission signal;
a power amplifier, configured to amplify the RF transmission signal to generate an amplified RF transmission signal to an antenna; and
a first phase compensation circuit, coupled to an output terminal or an input terminal of the first baseband amplifier, configured to compensate for a phase of the baseband transmission signal; or coupled to an output terminal or an input terminal of the power amplifier, configured to compensate for a phase of the amplified RF transmission signal.

2. The transceiver of claim 1, wherein the first phase compensation circuit is coupled to the output terminal or the input terminal of the first baseband amplifier and is configured to compensate for the phase of the baseband transmission signal; and the transmitting circuit further comprises:
a second phase compensation circuit, coupled to the output terminal or the input terminal of the power amplifier, configured to compensate for the phase of the amplified RF transmission signal.

3. The transceiver of claim 1, wherein the first baseband amplifier or the power amplifier has a gain switching function, and the transceiver further comprises:
a control circuit, coupled to the first phase compensation circuit, configured to control a configuration of the first phase compensation circuit according to a gain value of the first baseband amplifier or a gain value of the power amplifier, so as to compensate for a phase difference caused by the first baseband amplifier on the baseband transmission signal during gain switching, or to compensate for a phase difference caused by the power amplifier on the amplified RF transmission signal during gain switching.

4. The transceiver of claim 3, wherein the first phase compensation circuit comprises:
a switched capacitor array;
wherein the control circuit controls a capacitance value of the switched capacitor array according to a gain value of the first baseband amplifier or a gain value of the power amplifier.

5. The transceiver of claim 4, wherein the first phase compensation circuit further comprises:
a switched inductor array;
wherein the control circuit controls the capacitance value of the switched capacitor array and an inductance value of the switched inductor array according to the gain value of the first baseband amplifier or the gain value of the power amplifier.

6. The transceiver of claim 4, wherein the first phase compensation circuit further comprises:
a switched resistor array;
wherein the control circuit controls the capacitance value of the switched capacitor array and a resistance value of the switched resistor array according to the gain value of the first baseband amplifier or the gain value of the power amplifier.

7. The transceiver of claim 3, wherein the first phase compensation circuit further comprises:
a switched resistor array; and
a capacitor connected in parallel with the switched resistor array;
wherein the control circuit controls a resistance value of the switched resistor array according to a gain value of the first baseband amplifier or a gain value of the power amplifier.

8. The transceiver of claim 1, further comprising:
a receiving circuit, comprising:
a low-noise amplifier, configured to amplify a RF receiving signal to generate an amplified RF receiving signal;
a second mixer, configured to mix the amplified RF receiving signal using a second oscillation signal to generate a baseband receiving signal;
a second baseband amplifier, configured to amplify the baseband receiving signal to generate an amplified baseband receiving signal; and
a second phase compensation circuit coupled to an output terminal or an input terminal of the low-noise amplifier, configured to compensate for a phase of the amplified RF receiving signal; or coupled to an output terminal or an input terminal of the second baseband amplifier, configured to compensate for a phase of the amplified baseband receiving signal.

9. The transceiver of claim 8, wherein the second phase compensation circuit is coupled to the output terminal or the input terminal of the low-noise amplifier, configured to compensate for the phase of the amplified RF receiving signal; and the receiving circuit further comprises:
a third phase compensation circuit, coupled to the output terminal or the input terminal of the second baseband amplifier, configured to compensate for the phase of the amplified baseband receiving signal.

10. The transceiver of claim 8, wherein the low-noise amplifier or the second baseband amplifier has a gain switching function, and the transceiver further comprises:
a control circuit, coupled to the second phase compensation circuit, configured to control a configuration of the second phase compensation circuit according to a gain value of the low-noise amplifier or a gain value of the second baseband amplifier, so as to compensate for a phase difference caused by the low-noise amplifier on the amplified RF receiving signal during gain switching, or to compensate for a phase difference caused by the second baseband amplifier on the amplified baseband receiving signal during gain switching.

11. The transceiver of claim 10, wherein the second phase compensation circuit comprises:
a switched capacitor array;
wherein the control circuit controls a capacitance value of the switched capacitor array according to a gain value of the low-noise amplifier or a gain value of the second baseband amplifier.

12. The transceiver of claim 11, wherein the second phase compensation circuit further comprises:
a switched inductor array;
wherein the control circuit controls the capacitance value of the switched capacitor array and an inductance value of the switched inductor array according to the gain value of the low-noise amplifier or the gain value of the second baseband amplifier.

13. The transceiver of claim 11, wherein the second phase compensation circuit further comprises:
a switched resistor array;
wherein the control circuit controls the capacitance value of the switched capacitor array and a resistance value of the switched resistor array according to the gain value of the low-noise amplifier or the gain value of the second baseband amplifier.

14. The transceiver of claim 10, wherein the second phase compensation circuit further comprises:
a switched resistor array; and
a capacitor connected in parallel with the switched resistor array;
wherein the control circuit controls a resistance value of the switched resistor array according to a gain value of the low-noise amplifier or a gain value of the second baseband amplifier.

15. A transceiver, comprising:
a receiving circuit, comprising:
a low-noise amplifier, configured to amplify a radio frequency (RF) receiving signal to generate an amplified RF receiving signal;
a mixer, configured to mix the amplified RF receiving signal using an oscillation signal to generate a baseband receiving signal;
a baseband amplifier, configured to amplify the baseband receiving signal to generate an amplified baseband receiving signal; and
a first phase compensation circuit, coupled to an output terminal or an input terminal of the low-noise amplifier, configured to compensate for a phase of the amplified RF receiving signal; or coupled to an output terminal or an input terminal of the baseband amplifier, configured to compensate for a phase of the amplified baseband receiving signal.

16. The transceiver of claim 15, wherein the first phase compensation circuit is coupled to the output terminal or the input terminal of the low-noise amplifier, configured to compensate for the phase of the amplified RF receiving signal; and the receiving circuit further comprises:
a second phase compensation circuit, coupled to the output terminal or the input terminal of the baseband amplifier, configured to compensate for the phase of the amplified baseband receiving signal.

17. The transceiver of claim 15, wherein the low-noise amplifier or the baseband amplifier has a gain switching function, and the transceiver further comprises:
a control circuit, coupled to the first phase compensation circuit, configured to control a configuration of the first phase compensation circuit according to a gain value of the low-noise amplifier or a gain value of the baseband amplifier, so as to compensate for a phase difference caused by the low-noise amplifier on the amplified RF receiving signal during gain switching, or to compensate for a phase difference caused by the baseband amplifier on the amplified baseband receiving signal during gain switching.

18. The transceiver of claim 17, wherein the first phase compensation circuit comprises:
a switched capacitor array;
wherein the control circuit controls a capacitance value of the switched capacitor array according to a gain value of the low-noise amplifier or a gain value of the baseband amplifier.

19. The transceiver of claim 18, wherein the first phase compensation circuit further comprises:
a switched inductor array;
wherein the control circuit controls the capacitance value of the switched capacitor array and an inductance value of the switched inductor array according to the gain value of the low-noise amplifier or the gain value of the baseband amplifier.

20. The transceiver of claim 18, wherein the first phase compensation circuit further comprises:
a switched resistor array;
wherein the control circuit controls the capacitance value of the switched capacitor array and a resistance value of the switched resistor array according to the gain value of the low-noise amplifier or the gain value of the second baseband amplifier.
